(19) United States
(12) Patent Application Publication
(10) Pub. No.: US 2002/0044423 A1
(43) Pub. Date: Apr. 18, 2002

(54) Method and apparatus for mounting and packaging electronic components

(76) Inventors: Anthony A. Primavera, Windsor, NY (US); Peter Borgesen, Binghamton, NY (US)

Correspondence Address: William C. Rowland, BURNS, DOANE, SWECKER & MATHIS, L.L.P., P.O. Box 1404, Alexandria, VA, 22313-1404, US

(21) Appl. No.: 09/966,981

(22) Filed: Oct. 1, 2001

Related U.S. Application Data
(63) Continuation of application No. 09/311,977, filed on May 14, 1999, now abandoned.

(51) Int. Cl. H05K 7/20

(52) U.S. Cl. 361/704

(57) ABSTRACT

A component package having a substrate. The substrate has a component or chip section and a separate assembly section. An array of component pads are disposed on the component section and are adapted to be electrically connected to a component. An array of assembly contact pads are disposed on the assembly section and are adapted to be connected to a next level assembly, such as a printed circuit board. The component contact pads are electrically connected to the assembly contact pads by electrical conductors affixed to the substrate. At least a portion of the substrate between the component section and the assembly section is flexible. The assembly section of the substrate can be secured to a rigid carrier and a casing (or overmolded top) can be mounted to the rigid carrier so as to protect a component enclosed in the package.

### FIELD OF THE INVENTION

The present invention relates to packaging of electronic components including integrated circuit chips and their attachment to printed circuit boards or the next level assembly.

### BACKGROUND OF INVENTION

With the development of increased density, higher speed performance, increased I/O and enhanced functionality in integrated circuit (IC) chips, there has consequently developed a need for higher density interconnection between the chip and the printed circuit board. At the same time, there has been a considerable reduction in available board real estate, adding to the desire for high density interconnection.

One solution to this problem has been direct chip attach (DCA) technology in which the IC device (“die” or “chip”) is attached directly to the circuit board substrate. In one form of DCA (“flip chip” assembly) the silicon chip is attached directly to the printed circuit board substrate through an array of solder joints which provide both the mechanical and electrical connection between the chip and the circuit board. During thermal excursions, however, the chip and substrate generally expand and contract differently due to differences between their effective coefficients of thermal expansion (CTE). This leads to repeated straining, and eventually fatigue and failure, of the interconnecting solder joints. This effect is considered too damaging for most applications, and the chips must usually be underfilled with an adhesive, which effectively bonds the chips to the board substrate, thus strongly reducing the load on the solder joints. This solution has the disadvantage that underfilling is in itself an unattractive (slow and expensive) process step. Also, underfilled chips are difficult to test before assembly and cannot be removed by reasonable means after curing of the adhesive, if the chips or board are defective.

An alternative solution is to attach a flip chip to a sufficiently flexible (tape) substrate suspended within a stiffener ring. While it may not be necessary to underfill such a chip, all solder joints connecting the package to the printed circuit board must be mounted underneath the stiffener ring, i.e. well outside the chip region. This requires substantial additional board real estate.

Another common alternative to DCA is the mounting of a chip in a Ball Grid Array (BGA) package. Such a package is then attached to the printed circuit board through an array of solder joints. In a ceramic BGA the thermal expansion of the ceramic package substrate is better, although not perfectly, matched to the chip, so that it may not be necessary to underfill a small flip chip in such a package. However, large chips still require underfilling. Also, the ceramic substrates are expensive and the thermal mismatch between these and the printed circuit board may now become an issue. In a plastic BGA the thermal expansion of the organic package substrate is well matched to the printed circuit board and the size of the chip region may be minimized by flip chip attachment to the organic substrate. However, the BGA substrate needs to be reasonably rigid to ensure planarity of the solder joint array on the bottom, so a flip chip usually has to be underfilled. If the chip is firmly attached to the substrate the composite (effective) CTE in the chip region approaches that of the chip. The solder joints connecting the package to the printed circuit board should therefore preferably be placed outside of the chip region. Thus, most BGAs require considerably more real estate than the chip itself and are relatively expensive to manufacture.

Recently, a number of Chip Scale Package (CSP) concepts have been proposed and developed for limiting real estate requirements. In general, however, these are even more difficult and expensive to manufacture, and the reliability is often questionable. Alternatives to BGA and CSP packages include TAB and SMT packages. All of these require substantial real estate and offer limited I/O capabilities.

In addition to the above difficulties, the connection of multiple chips in close proximity on a multi-chip module requires at least a proportional amount of additional real estate. While the stacking of chips on a single module may reduce real estate requirements, the manufacturing is quite complicated and expensive.

### SUMMARY OF THE INVENTION

It is, therefore, an object of the present invention to provide an inexpensive and reliable means for mounting an electronic component including IC chips to a next level assembly.

Another object of the present invention is to provide an inexpensive and reliable package for an IC chip or other component.

A further object of the present invention is to provide an IC chip or other component package which requires minimal mounting real estate.

Yet another object of the invention is to provide an inexpensive and reliable means for mounting multiple IC chips or other components utilizing a minimal amount of board real estate.

The above and other objects are achieved in accordance with a first aspect of the present invention by a package substrate having a chip section and an assembly section. An array of chip contact pads is disposed on the chip section and chip contact pads are adapted to be electrically connected to a chip. An array of assembly contact pads is disposed on the assembly section and the assembly contact pads are adapted to be connected to a next level assembly, such as a printed circuit board. The chip contact pads are electrically connected to the assembly contact pads by electrical conductors affixed to the package substrate. At least a portion of the package substrate between the chip section and the assembly section is flexible

In a second aspect of the present invention the assembly section of the package substrate is secured to a rigid carrier and a lid (or overmolded top) is mounted to the rigid carrier so as to protect a chip enclosed in the package from physical damage. The chip is secured within the package by an adhesive or elastomer layer connecting the chip (or the package substrate) to the rigid carrier or the lid of the package.

In a third aspect of the present invention the package substrate includes additional chip sections for mounting multiple chips within a single package.

These and other objects, features and advantages of the present invention will be apparent and filly understood from the following detailed description of the preferred embodiments, taken in connection with the appended drawings in which like reference numerals describe corresponding features.

### BRIEF DESCRIPTION OF THE DRAWINGS

FIG. 1A is side elevational view of a package substrate for mounting a chip in accordance with the present invention.

FIG. 1B is a top view of the package substrate of FIG. 1A.

FIG. 1C is a side elevational view of the package substrate of FIG. 1A with the assembly section folded under the chip section.

FIG. 2 is a side elevational view of a package substrate for mounting a chip in accordance with the present invention with a Si-blank attached to the substrate, opposite the chip.

FIG. 3 is a cross-sectional view of a package substrate for use in the present invention.

FIG. 4 is a cross-sectional view of an alternative package substrate for use in the present invention.

FIG. 5 is a top view of an embodiment of the package substrate having multiple assembly sections in accordance with the present invention.

FIG. 6A is a side elevational view of a package substrate for mounting multiple chips in accordance with the present invention.

FIG. 6B is a side elevational view of the package substrate of FIG. 6A with the assembly section folded under the chip section.

FIG. 7A is a side elevational view of an alternative package substrate for mounting multiple chips in accordance with the present invention.

FIG. 7B is a side elevational view of the package substrate of FIG. 7A with the assembly section folded under the chip sections.

FIG. 8 is a side elevational view of another alternative package substrate for mounting multiple chips in accordance with the present invention.

FIG. 9 is a side elevational view of yet another alternative package substrate for mounting multiple chips in accordance with the present invention.

FIGS. 10A-10H illustrate the fabrication of a chip package in accordance with the present invention.

FIG. 11 is a partial cross-sectional view of an alternative embodiment a chip package in accordance with the present invention.

FIG. 12 is a partial cross-sectional view of another alternative embodiment of the chip package in accordance with the present invention in which an overmold compound is used in place of a lid.

FIG. 13 is a partial cross-sectional view of yet another alternative embodiment of the chip package in accordance with the present invention in which the lid encloses the entire package substrate.

FIGS. 14A and 14B are partial cross-sectional views of further embodiments of the chip package in accordance with the present invention in which an adhesive is used to secure the chip within the package.

FIG. 15 is a partial cross-sectional view of an embodiment of the chip package in accordance with the present invention with a Si-blank attached to the substrate, opposite the chip.

FIG. 16 is a partial cross-sectional view of a chip package having a heat sink in accordance with the present invention.

FIG. 17 is a partial cross-sectional view of a chip package having an integral copper rigid carrier/heat sink in accordance with the present invention.

FIG. 18 is a partial cross-sectional view of an alternate embodiment of the chip package of FIG. 17 in which a thermal potting compound is used in place of a lid.

FIG. 19 is a partial cross-sectional view of a chip package for two chips in accordance with the present invention.

FIG. 20 is a partial cross-sectional view of a chip package for multiple chips in accordance with the present invention.

### DETAILED DESCRIPTION OF THE PREFERRED EMBODIMENT

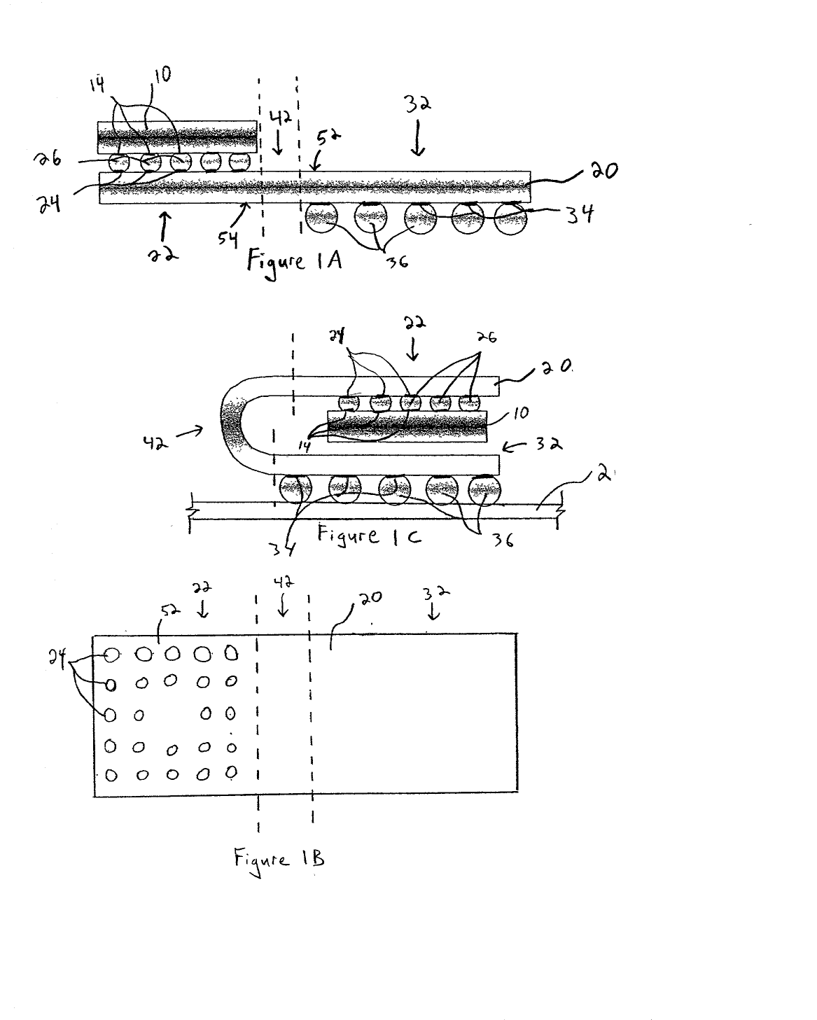

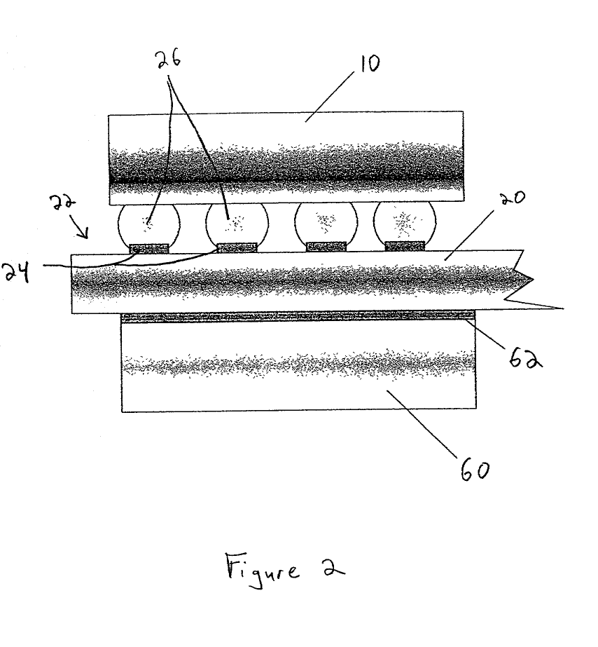

Referring to FIGS. 1A-1C, a first embodiment of the present invention is illustrated. This embodiment includes a planar package substrate 20, which has a top surface 52 and a bottom surface 54. In addition, for the purposes of this description, the package substrate 20 may be described as having a chip section 22, an assembly section 32 and an intermediate section 42, where the intermediate section 42 is located between the chip section 22 and the assembly section 32.

In the chip section 22, an array of chip contact pads 24 is located on the top surface 52 of the package substrate 20 (see FIG. 1B). The arrangement of the chip contact pads 24 is selected to correspond to the arrangement of die pads 14 on the chip 10 to be mounted and/or packaged. An array of assembly contact pads 34 is similarly located on the bottom surface 54 of the package substrate 20 in the assembly section 32. The arrangement of the assembly contact pads 34 is selected to meet the requirements of mounting the package to the next level assembly, for example, a printed circuit board.

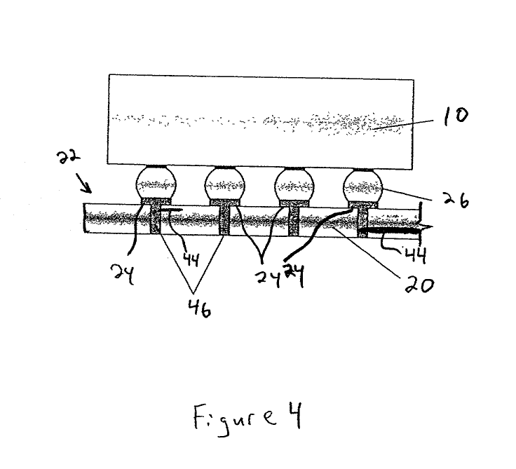

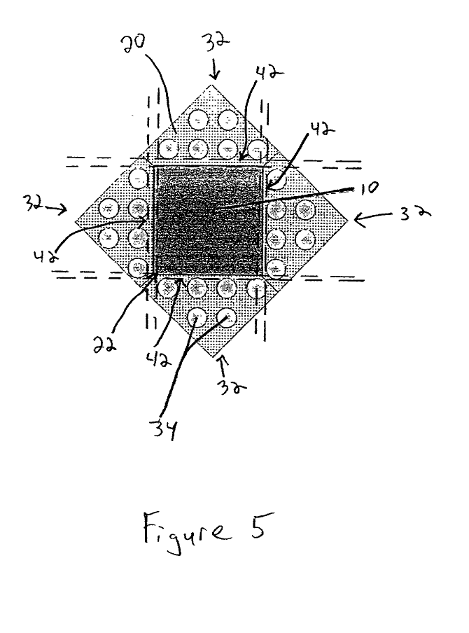

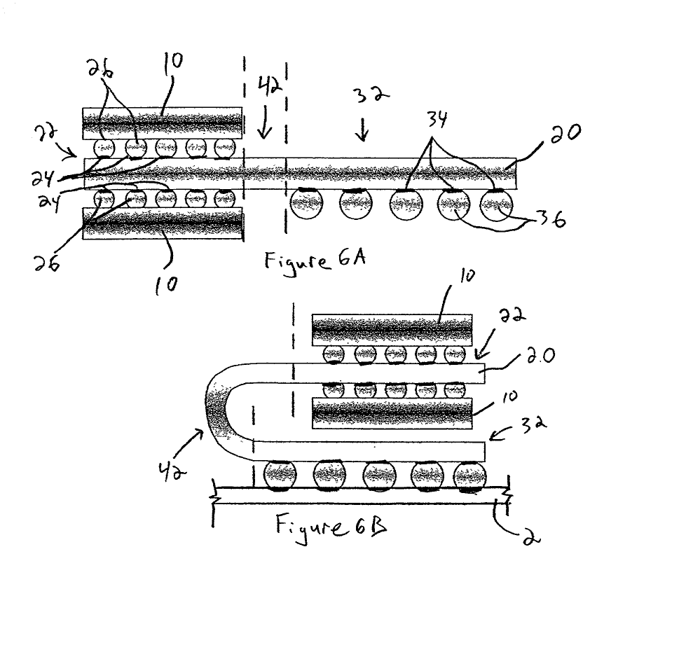

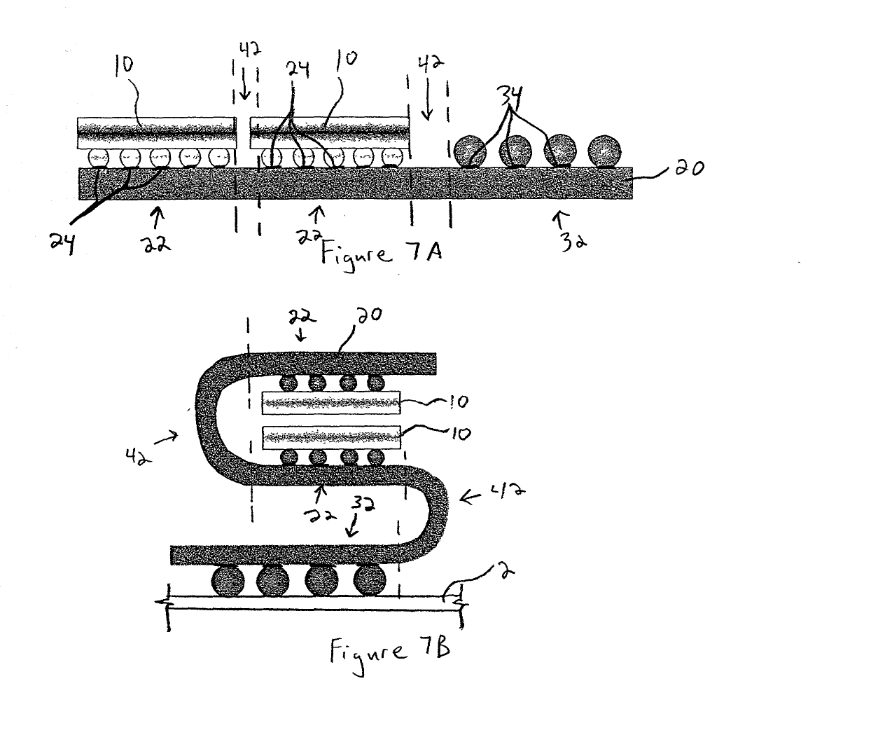

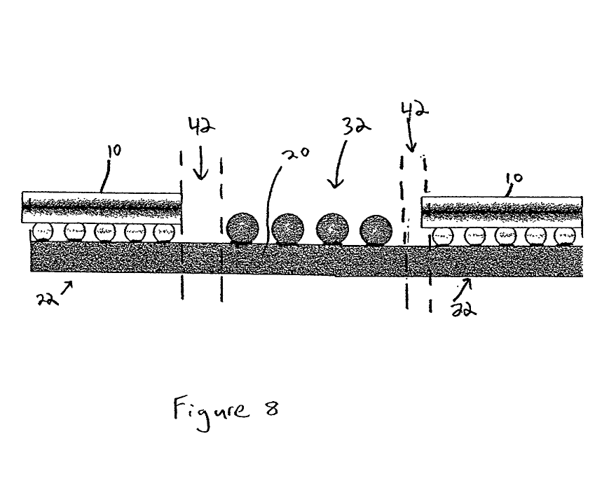

The chip contact pads 24 are electrically connected by a plurality of conductors 44 (see FIGS. 3 and 4) to the assembly contact pads 34. Thus, by mounting the chip 10 to the package substrate 20, and mounting the substrate 20 to the next level assembly, the chip 10 will be electrically connected to the next level assembly. It should be understood that all or only selected ones of the chip contact pads may be connected to the assembly contact pads, depending on the circuit design requirements. The conductors are affixed to the intermediate section 42 of the package substrate 20 (as described below) and the intermediate section 42 is flexible so that the assembly section 32 may be folded under the chip section 22 and mounted to the next level assembly (e.g., circuit board 2), as illustrated in FIG. 1C. In this manner, the when mounted to the next level assembly, the entire package requires only slightly more real estate than the chip 10 itself. It should be understood that terms such as “under” and phrases such as “folded under” are used throughout this application in an illustrative sense merely to indicate the relative positioning of the referenced elements.

A component (shown as chip 10) is mounted to the package substrate 20 using standard DCA technology, for example, high-Pb solder joints 26. The package substrate 20 is likewise mounted to the next level assembly using methods well known in the art, for example, by eutectic solder balls 36 deposited on the assembly contact pads 34. This arrangement allows for reflow of the eutectic solder balls 36 for mounting/removing the package from the next level assembly without disturbing or compromising the mounting of the chip 10 to the package substrate 20. It should, however, be apparent to one of ordinary skill in the art that other methods of attaching the chip 10 to the package substrate 20 and the package substrate 20 to the next level assembly may be used. For example, other acceptable methods of attaching the chip 10 to the package substrate 20 include isotropic/anisotropic conductive adhesives, Au bumps with adhesives or other (lead free) metallurgies. Likewise other methods for attaching the package substrate 20 to the next level assembly include high-Pb solder balls, nickel posts or other rigid solderable structures, if the printed circuit board pads are solder coated. As should be apparent from the disclosure herein, the overall footprint of the complete package will be determined in large part by the mounting technique chosen for the connecting the package to the next level assembly. For example, if eutectic solder balls 36 are used, the acceptable size and pitch of the solder balls 36 will dictate the minimum achievable package size.

Because no section of the package substrate 20 is directly connected to both the chip 10 and the next level assembly, the expansion and contraction of each section will only be influenced by, at most, one of the chip 10 and next level assembly during thermal excursions. Consequently, provided a sufficiently flexible substrate is used for the package substrate 20, the expansion of the chip section 22 of the package substrate 20 will closely match that of the chip 10 and the stress produced in the chip solder joints 26 will be minimized during thermal excursions. Thus, no underfill of the chip 10 will be required to prevent fatigue of the solder joints 26. Likewise, the expansion of the assembly section 32 of the package substrate 20 will closely match that of the next level assembly and thus the stress produced in the eutectic solder joints 36 will similarly be minimized by using a sufficiently flexible package substrate 20.

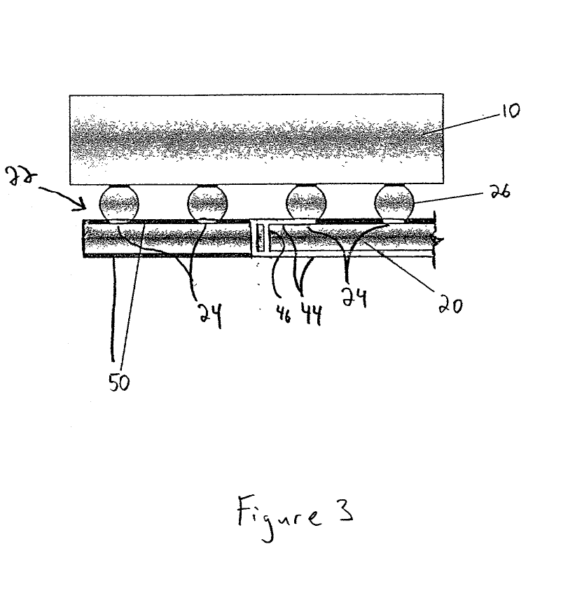

Optionally, a piece of material (“blank”) 60 having a CTE closely matching that of the chip 10 may be laminated or glued using an adhesive 62 to the chip section 22 of the package substrate 20 on the surface opposite the array of chip contact pads 24. This will force the thermal expansion of the package substrate 20 to better match that of the chip 10 and minimize warpage due to thermal expansion during assembly. FIG. 2 illustrates a Si-blank 60 mounted by an adhesive 62 to the package substrate 20 directly under the chip 10. Use of a Si-blank 60 also has the advantage of providing planarity of the chip section 22 of the package substrate 20 during assembly.

The package substrate 20 of the illustrated embodiments is a conventional, flexible substrate formed, for example, of polyimide. It should, however, be understood that other flexible substrates may be used. If only a small number of interconnections are required between the chip contact pads 24 and assembly contact pads 34, surface traces on the package substrate 20 may be used as the required conductors 44, with vias 46 where appropriate, to connect the two arrays of contact pads. In this case, a solder mask 50 is required, and should be applied to both surfaces of the package substrate 20, as illustrated in FIG. 3, to avoid warpage due to thermal mismatch during assembly. Where a blank 60 is secured to the substrate 20, as described above, a solder mask 50 may only be required on the top surface 52. Alternatively, placing the array of chip contact pads 24 and the array of assembly contact pads 34 on the same surface may simplify the manufacturing process and may even eliminate the need for vias 46. Where a larger number of interconnections are required between the chip contact pads 24 and assembly contact pads 34, the flexible substrate 20 may have vias 46 in the contact pads 24 connecting multiple layers of conductors 44 in the package substrate 20. This would eliminate the need for solder masks 50 as seen in FIG. 4.

In another alternative embodiment, the package substrate 20 may include more than one assembly section 32, each separated from the chip section 22 by a flexible intermediate section 42, as illustrated in FIG. 5. The assembly sections 32 are positioned all around the chip section 22 and the chip contact pads 24 are on the same surface of the substrate 20 as the assembly contact pads 34, thereby simplifying the connection between chip contact pads 24 and assembly contract pads and minimizing the number of layers required in the package substrate 20. Each assembly section 32 of the substrate 20 in FIG. 5 is triangular in shape so that all four assembly sections 32 may be folded under the chip section 22 when mounted to the next level assembly. As in the previously described embodiments, this allows the whole package to be only slightly larger than the chip 10 itself, minimizing the required board real estate. To simplify mounting of such a structure to the next level assembly, all of the assembly sections 32 of the flexible package substrate 20 are attached (e.g., by an appropriate adhesive) to a rigid carrier after being folded under the chip section 22.

By varying the size and geometry of the package substrate 20, the mounting of multiple components or chips 10 in a single package may easily be accomplished. FIG. 6A illustrates a package substrate 20 similar to that illustrated in FIG. 1A. In this embodiment, however, a second array of chip contact pads 24 is located on the bottom surface 54 of the package substrate 20 in the chip section 22, directly below the first array of chip contact pads 24. The second array of chip contact pads 24 is electrically connected to the assembly contact pads 34. It should be noted, however, that all (or a selected number) of the pads in the second array of chip contact pads 24 may be connected directly to pads in the first array of chip contact pads 24 rather than to the assembly contact pads 34, the exact configuration and interconnection being dictated, in part, by the package design requirements. Like the embodiment of FIG. 1A, the package substrate 20 of FIG. 6A includes a flexible intermediate section 42 between the chip section 22 and the assembly section 32. Referring to FIG. 6B, it may be seen that this allows the assembly section 32 to be folded under the chip section 22 and mounted to the next level assembly (circuit board 2), as previously described. Comparing FIG. 6B to FIG. 1C, it may be seen that the package with two chips 10 does not require significantly more board real estate than the package having just one chip 10.

The mounting of multiple chips 10 in a single package may also be achieved by adding additional chip sections 22. Referring to FIG. 7A, the mounting of two chips 10 to a single substrate 20 is accomplished by providing two adjacent chip sections 22 (each with an array of chip contact pads 24) and a single assembly section 32 (with an array of assembly contact pads 34). In the embodiment of FIG. 7A, the chip contact pads 24 and the assembly contact pads 34 are all on the same surface of the substrate 20, however, other arrangements may obviously be implemented. As in the embodiment of FIG. 1A, there is a flexible intermediate section 42 between the assembly section 32 and the first chip section 22 which allows the assembly section 32 to be folded under the chip sections 22 for mounting to the next level assembly (circuit board 2). Optionally, a second intermediate section 42 is included between the two chip sections 22 to allow the second chip section 22 to be folded on top of the first, as shown in FIG. 7B. Again, this allows the package having more than one chip 10 to occupy approximately the same amount of board real estate as a package having a single chip 10.

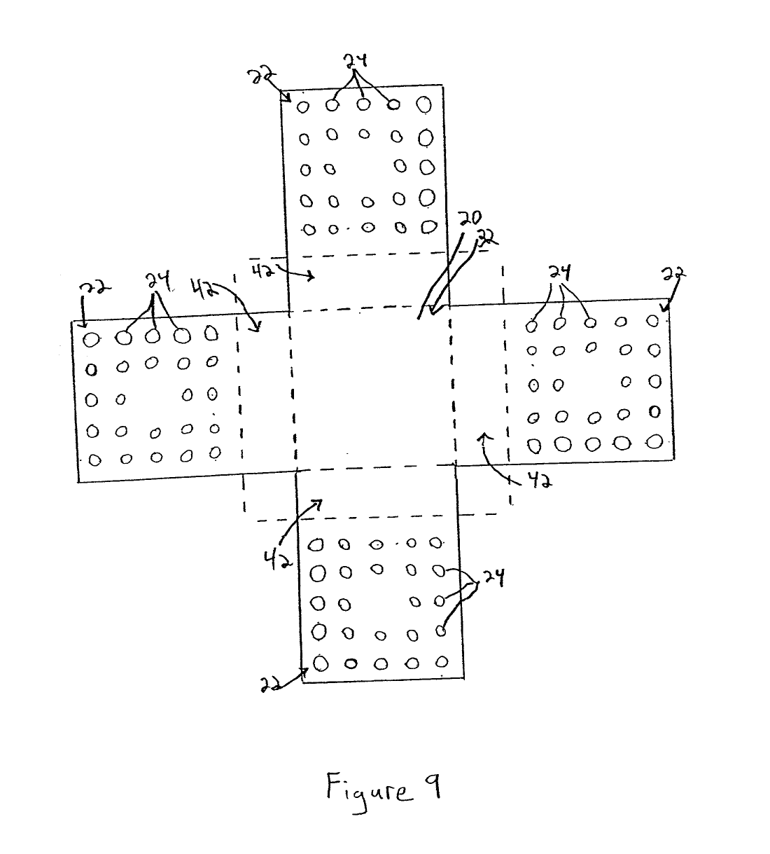

To simplify the connection of the chip contact pads 24 to the assembly contact pads 34, additional chip sections 22 in a multiple chip application may, alternatively, be added adjacent to the assembly section 32. FIG. 8 illustrates an assembly section 32 located between two chip sections 22 and FIG. 9 illustrates an assembly section 32 located in the middle of four chip sections 22. In both cases, a flexible intermediate section 42 is located between the chip sections 22 and the assembly section 32 to allow the chip sections 22 to be folded over the assembly section 32. Thus, in both cases, the entire package requires only slightly more real estate than a single chip 10. In all of the above embodiments, as well as those described below, it should be understood that the arrays of chip contact pads 24 and the arrays of assembly contact pads 34 may all be affixed to the same surface of the package substrate 20, or they may be located on different surfaces.

Using the above basic disclosure, many different packages may be constructed. In each package, the chip 10 should be physically secured within the package in a manner such that the chip 10 does not significantly affect the deformation of the substrate 20 in the assembly section 32. In addition, the assembly section 32 is preferably affixed to a rigid carrier 70, more preferably one having a CTE that closely matches that of the circuit board (or next level assembly) to which the package is to be mounted. This provides the rigid support and planarity to aid in mounting of the package, while at the same time forcing the thermal expansion of the substrate 20 in the assembly section 32 to better match that of the circuit board. Although the rigid carrier in the above and below described embodiments is illustrated as a separate element, it should be understood that the rigid carrier may easily be formed as an integral part of the assembly section, as would be understood by one of skill in the art.

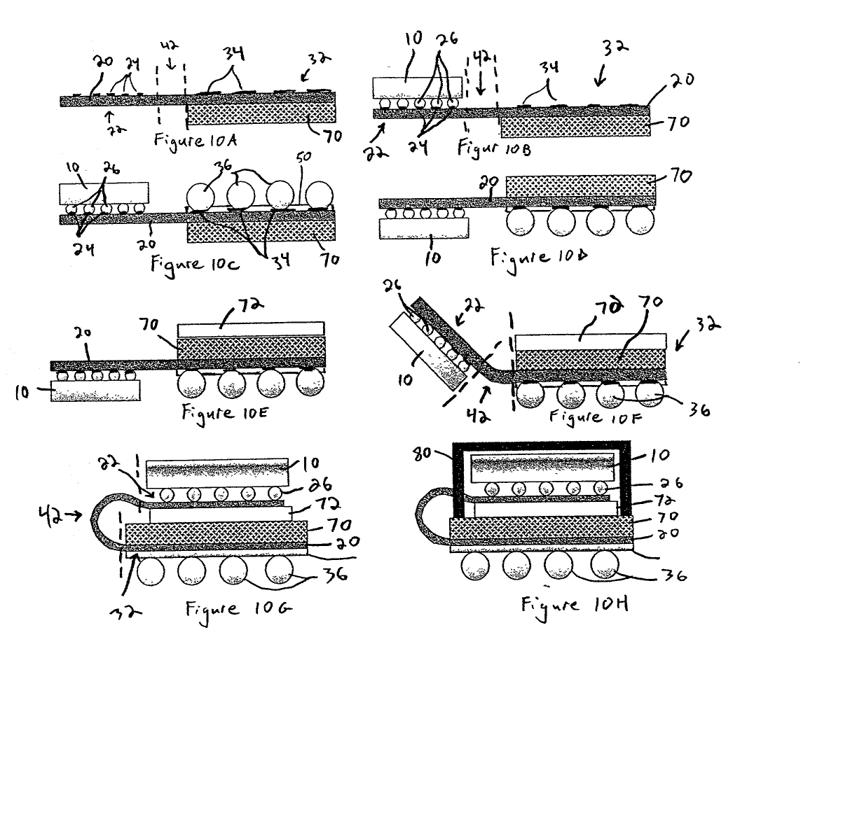

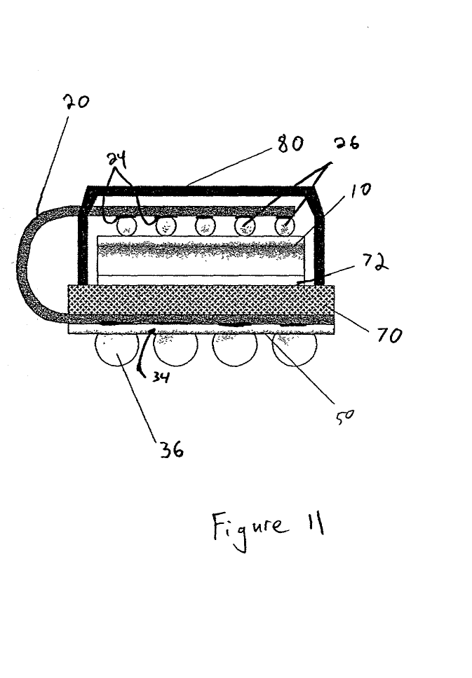

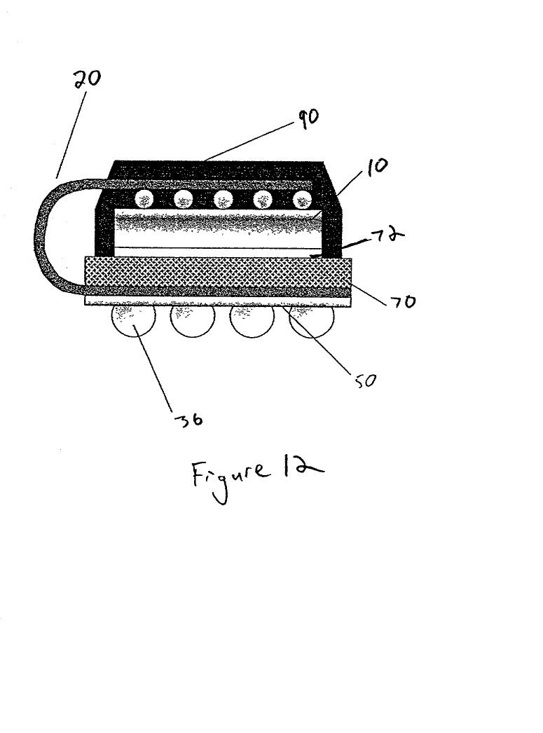

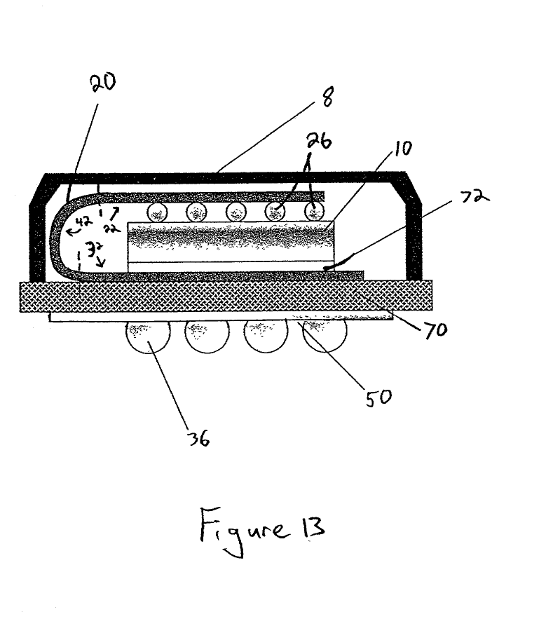

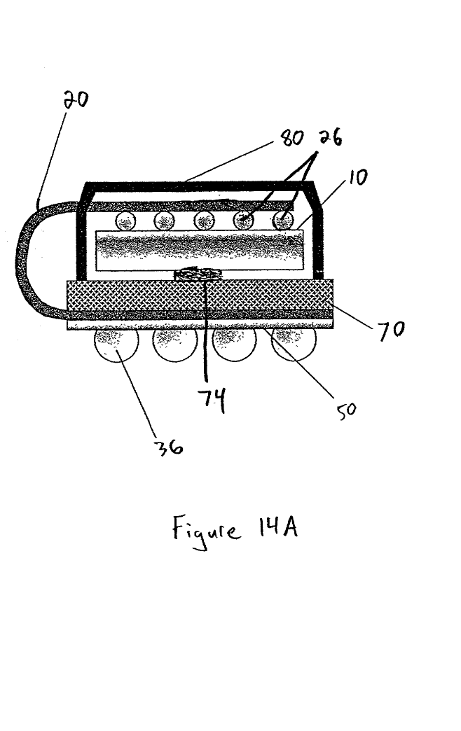

Referring to FIGS. 10A-10H, the fabrication of a first embodiment of a complete chip package according to the present invention is illustrated. First, a flexible package substrate 20 is formed including the array of chip contact pads 24 in a chip section 22, the array of assembly contract pads in an assembly section 32 and the conductors between the two in an intermediate section 42, as previously described. A rigid carrier 70 is laminated to the assembly section 32 of the flexible substrate 20, on the opposite surface of the assembly contact pads 34. (FIG. 10A) The rigid carrier 70 is formed of BT or FR-4 epoxy glass laminate so that the CTE of the rigid carrier 70 closely matches that of the printed circuit board to which the package will eventually be mounted. It should be noted that to achieve manufacturing efficiency, several substrate/rigid carrier combinations may be constructed simultaneously as an FR-4 panel with cut-out regions having the flexible package substrate only.

Next the chip 10 is mounted to the chip contact pads 24 using standard DCA methods. (FIG. 10B) (If the chip 10 is to be mounted by high-Pb solder balls 26, the chip 10 may have to be mounted to the package substrate 20 before the rigid carrier 70 is secured to the substrate 20, depending on the material used for the rigid carrier 70 and its tolerance to temperatures required to reflow the high-Pb solder balls 26.) The solder mask 50 is then applied and the larger eutectic solder balls 36 are placed on the assembly contact pads 34, again using well-known methods. (FIG. 10C) The package is then turned over (FIG. 10D) and an elastomer layer 72 is attached to the back of the rigid carrier 70. (FIG. 10E) The chip section 22 of the substrate 20 is then folded over (FIG. 10F) to attach the chip section 22 (and hence the chip 10) to the exposed surface of the elastomer layer 72 (FIG. 10G). (If numerous packages are being constructed simultaneously as a panel, as described above, this step will first require separating the individual package units from the panel.) Finally, a lid 80 is secured to the rigid carrier,70, either by a snap fit or an appropriate adhesive, to protect the chip 10 from physical damage and the entire package may be mounted to the next level assembly (circuit board 2), as illustrated in FIG. 10H.

The elastomer layer 72 physically secures the chip 10 within the package, when required, yet the elastomer material is sufficiently flexible to prevent the chip 10 from affecting the deformation of the rigid carrier 70 during thermal excursions. One acceptable material for the elastomer layer 72 is a polychloroprene elastomer commercially marketed as Aquastik™ 1120 by DuPont Dow Elastomers LLC.

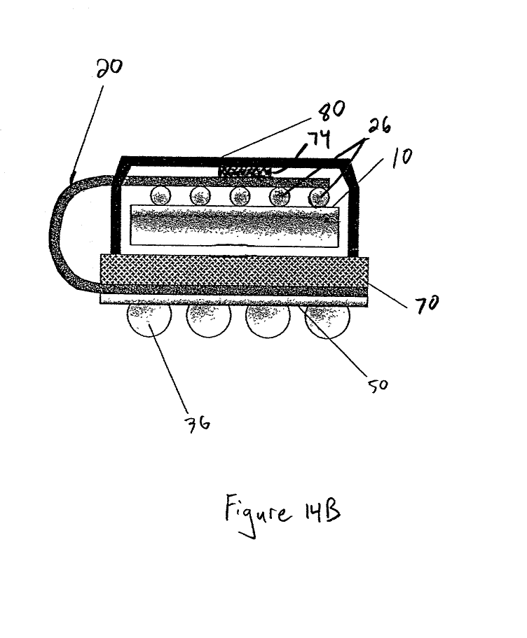

It should be understood, however, that other materials and other arrangements may be utilized to secure the chip within the package. For example, in one alternative embodiment, shown in FIG. 11, the chip contact pads 24 and assembly contact pads 34 are formed on opposite surfaces of the package substrate 20. Thus, when the chip section 22 is folded over the assembly section 32, the back of the chip 10, rather than the chip section 22, is secured directly to the elastomer layer 72. Again, provided the elastomer material is sufficiently flexible, the expansion of the chip 10 and rigid carrier 70 will not affect one another during thermal excursions.

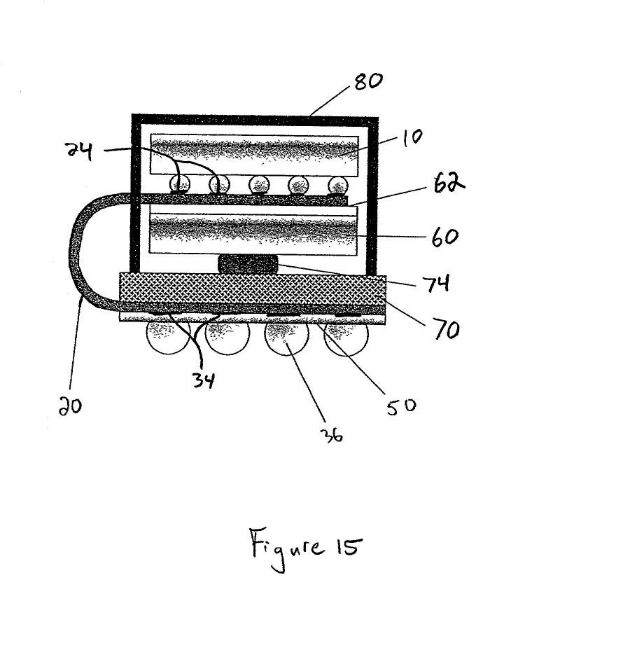

Turning to the embodiment of FIG. 12, the lid 80 of the package in FIG. 11 has been omitted and the entire package is overmolded with a mold compound 90. The mold compound is selected to minimize warpage, as in conventional packages. One suitable mold compound is the Plaskon® SMT-B family of epoxy molding compounds commercially available from Amoco Electronic Materials, Plaskon Division, of Alpharetta, Ga. It should be noted that the use of a molded cover 90 may also be used in subsequent embodiments as well. In addition, casings other than a lid 80 or molded cover 90 may be used to protect the chip 10 from physical damage, as will be understood by one of skill in the art.

If hermeticity is desired, the embodiment of FIG. 11 can be modified so that the entire package (i.e., including the flexible substrate 20) is enclosed within the lid 80. One way of accomplishing this (illustrated in FIG. 13) is to mount the rigid carrier 70 to the assembly section 32 of the package substrate 20 on the same surface as the assembly contact pads 34. The assembly contact pads are then electrically connected to an array of contact pads (not shown) in the rigid carrier using well known methods, including vias where appropriate. The solder mask 50 is then applied to the rigid carrier 70 and the larger eutectic solder balls 36 are placed on the contact pads of the rigid carrier, again using well-known methods. In this manner, the assembly contact pads 34 in the assembly section 32 are electrically connected to the next level assembly. Similar modifications can be made to the embodiment of FIG. 12 and to the embodiments described below.

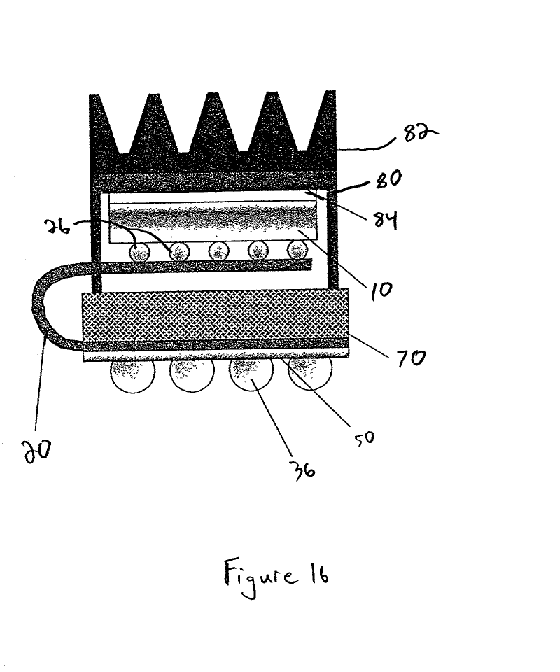

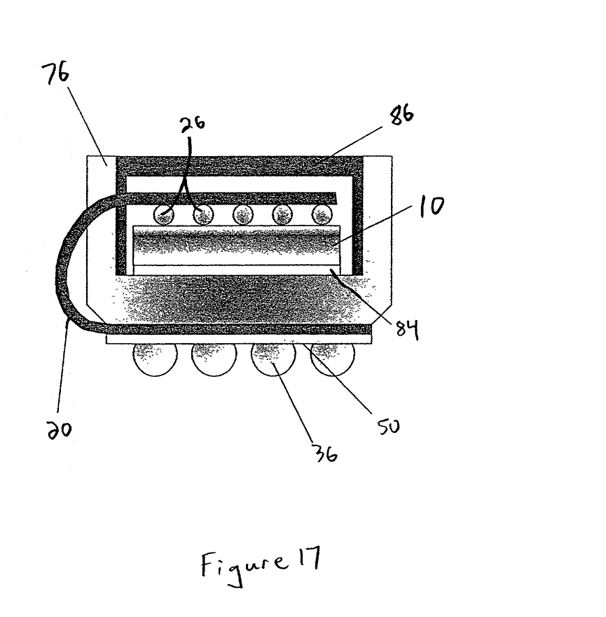

In another embodiment, an adhesive 74 rather than an elastomer is used to attach the chip 10 (or chip section 22 of the substrate 20) to the rigid carrier 70. Preferably the adhesive 74 is one that deforms plastically during thermal excursions, thus minimizing the effect of the chip 10 on deformation of the rigid carrier 70. One acceptable adhesive is the non-filled dielectric interposer paste commercially marketed as Staystik 371 by Alphametals, Inc. of Jersey City, N.J. FIGS. 14A and 14B illustrate the acceptable locations for adhesive 74. In one embodiment shown in FIG. 14A, the back of the chip 10 is secured to the rigid carrier 70 using the adhesive 74. By limiting the area of adhesive coverage, the effect on carrier 70 deformation is further limited. Alternatively, the chip section 22 of the flexible substrate 20 may be secured to the inside of the lid 80 by the adhesive 74, as shown in FIG. 14B.

Conversely, if the chip contact pads 24 and assembly contact pads 34 are disposed on the same surface of the flexible substrate 20 (see, FIG. 10H), the chip 10 may be secured to the lid 80 by the adhesive 74 or the chip section 22 of the package substrate 20 may be secured to the rigid carrier 70 by the adhesive 74. Similarly, if a blank 60 is secured to the underside of the chip section 22, as described in connection with FIG. 2, either the chip 10 or the blank 60 can be secured by the adhesive 74 to the rigid carrier 70 or the lid 80. For example, FIG. 15 illustrates a package substrate 20 with the chip contact pads 24 and assembly contact pads 34 on the same surface. Thus, the Si-blank 60 is disposed on top of the rigid carrier 70 and under the chip 10 when the flex substrate 20 is folded. The Si-blank 60 is secured by an adhesive 74 to the top of the rigid carrier 70, thereby securing the chip 10 within the package. Other methods of securing the chip within the package should occur to those of skill in the art.

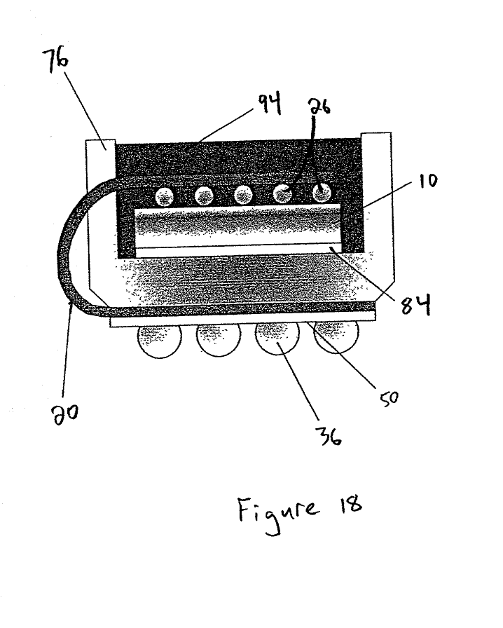

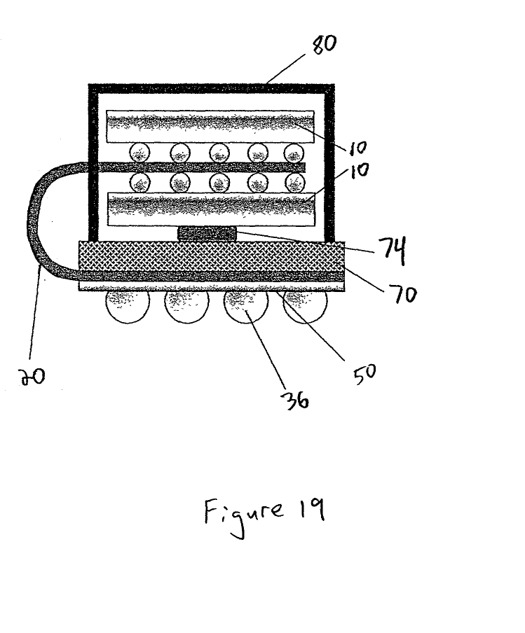

If effective cooling of the chip 10 is an issue, the backside of the chip 10 may be attached to the inside of a lid 80 having a heat sink 82 or heat spreader (FIG. 16) using a thermal compound 84 such as the aluminum nitride filled thermally enhanced paste commercially marketed as Staystik 272 by Alphametals, Inc. The heat sink 82 may be integral with the lid 80 or attached as a separate component. Alternatively, if the thermal compound 84 is sufficiently compliant to allow attachment of the chip 10 to a copper heat sink, the heat sink may be formed as an integrated copper rigid carrier/heat sink 76, as shown in FIG. 17. This is particularly effective on a FR-4 board since the thermal expansion of copper closely matches that of FR-4. A lid 86 (FIG. 17) or a thermal potting compound 94 (FIG. 18) is then used to cover the chip 10 and protect it from physical damage, as previously described.

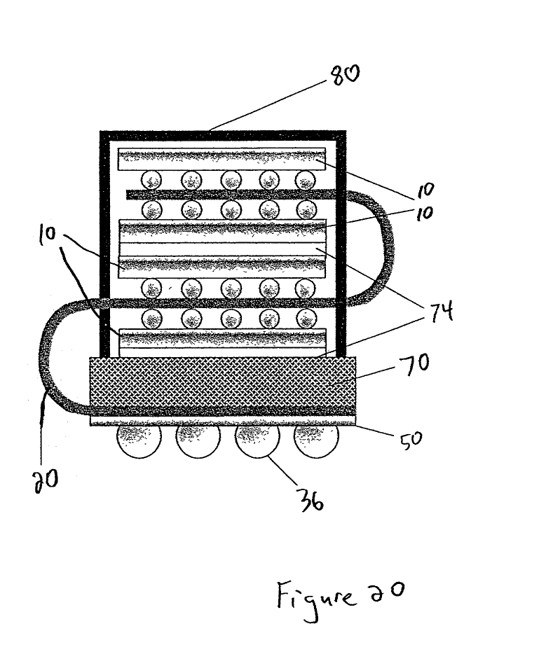

If multiple chips 10 are to be mounted in a single package, the mounting of multiple chips 10 as described in connection with FIGS. 6A-9 may be combined with any of the above described package configurations. For example, in the mounting shown in FIGS. 6A and 6B, two chips 10 are attached to opposite surfaces of a single chip section. Combining this mounting with the package illustrated in FIG. 14A, the bottom chip 10 is secured to the rigid carrier 70 of the package by an adhesive 74 placed on the back of the chip lo, as shown in FIG. 19. Alternatively, the top chip 10 may be secured to the lid 80 in a manner similar to FIG. 14B. In addition, if multiple chips 10 are attached combination of FIGS. 6A-6B and 7A-7B), after folding of the substrate 20, an adhesive 74 may be used to hold adjacent chips 10 secure to one another, as shown in FIG. 20. The stack of chips 10 may then be secured to either the rigid carrier 70 or the lid 80, as described in connection with the previous embodiments.

The present invention has been described in terms of illustrated embodiments thereof. Other embodiments (and combinations of the above embodiments), features and variations within the scope of the appended claims will, given the benefit of this disclosure, occur to those having ordinary skill in the art.

What is claimed is:

1. A substrate for mounting at least one component to a next level assembly, said substrate comprising:
an assembly section;
a plurality of assembly contact pads disposed on said assembly section and adapted to be electrically connected to said next level assembly;
at least one component section;
a plurality of component contact pads disposed on said component section and adapted to be electrically connected to said component, said plurality of component contact pads being electrically connected to said plurality of assembly contact pads; and
at least one intermediate section disposed between said assembly section and said component section, wherein at least a portion of said intermediate section is flexible such that said assembly section may be folded.

2. The substrate of claim 1 wherein said component section, said assembly section and said intermediate section are formed of a flexible planar substrate material.

3. The substrate of claim 2 wherein said substrate material is formed of polyimide.

4. The substrate of claim 2 wherein said substrate material comprises multiple layers.

5. The substrate of claim 1 wherein said plurality of assembly contact pads are disposed on a first surface of said substrate and wherein said plurality of component contact pads are disposed on a second surface of said substrate.

6. The substrate of claim 1 wherein said plurality of assembly contact pads and said plurality of component contact pads are both disposed on a first surface of said substrate.

7. The substrate of claim 1 wherein said plurality of assembly contact pads are disposed on a first surface of said substrate and wherein said plurality of component contact pads are disposed on first and second surfaces of said substrate.

8. The substrate of claim 1 wherein said component is a first device chip, said component section is a first chip section, said plurality of component contact pads is a first plurality of chip contact pads, and said intermediate section is a first intermediate section, said substrate further comprising:
a second component section disposed adjacent to said assembly section;
a second plurality of component contact pads disposed on said second chip section and adapted to be electrically connected to a second device chip, said second plurality of chip contact pads being electrically connected to said plurality of assembly contact pads or to said first plurality of chip contact pads; and
a second intermediate section disposed between said assembly section and said second chip section, wherein at least a portion of said second intermediate section is flexible such that said second chip section may be folded over said assembly section.

9. A substrate for mounting at least one component to a next level assembly, said substrate comprising:
means for electrically connecting said substrate to said next level assembly;
means for electrically connecting said substrate to said component;
means for electrically connecting said component to said next level assembly; and
wherein said means for electrically connecting said component to said next level assembly may be folded.

10. A method for mounting at least one component to a next level assembly, said method comprising:
mounting said component to a component section of a substrate such that said component is electrically connected to a plurality of component contact pads disposed on said component section;
mounting an assembly section of said substrate to said next level assembly such that said next level assembly is electrically connected to a plurality of assembly contact pads disposed in said assembly section, said plurality of assembly contact pads being electrically connected to said component contact pads; and
folding said component section over said assembly section.

11. A package for at least one component comprising:
a substrate having an assembly section, a component section and an intermediate section between said assembly section and said component section, wherein at least a portion of said intermediate section is flexible such that said assembly section may be folded under said component section;
a plurality of component contact pads disposed on said component section and adapted to be electrically connected to said component;
a plurality of assembly contact pads disposed on said assembly section and adapted to be electrically connected to a next level assembly, said plurality of assembly contact pads being electrically connected to said plurality of component contact pads;
a rigid carrier affixed to said assembly section; and
a casing surrounding said component and affixed to said rigid carrier.

12. The package of claim 11 wherein said casing comprises an overmold compound.

13. The package of claim 11 further comprising means to secure said component within said package.

14. The package of claim 11 wherein said casing hermetically seals said component within said package.

15. The package of claim 11 further comprising a heat sink affixed to said casing.

16. The package of claim 15 wherein said component is secured to said casing by a thermal compound.

17. The package of claim 11 wherein said rigid carrier is a heat sink.

18. The package of claim 17 wherein said rigid carrier is formed of copper.

19. A package for at least one integrated circuit chip comprising:
a substrate having an assembly section, a chip section and an intermediate section between said assembly section and said chip section, wherein at least a portion of said intermediate section is flexible such that said intermediate section may be folded;
a plurality of chip contact pads disposed on said chip section and adapted to be electrically connected to said chip;
a plurality of assembly contact pads disposed on said assembly section and adapted to be electrically connected to a next level assembly, said plurality of assembly contact pads being electrically connected to said plurality of chip contact pads;
means to rigidly support said assembly section; and
means to cover said chip.

20. A method for packaging at least one integrated circuit chip comprising:
mounting said chip to a chip section of a substrate such that said chip is electrically connected to a plurality of chip contact pads disposed in said chip section;
electrically connecting said plurality of chip contact pads to a plurality of assembly contact pads, said assembly contact pads being disposed in an assembly section of said substrate adjacent said chip section;
rigidly supporting said assembly section;
folding said chip section over said assembly section;
affixing a cover to said assembly section to surround said chip.
